(19) United States
(12) Patent Application Publication
(10) Pub. No.: US 2025/0201615 A1
(43) Pub. Date: Jun. 19, 2025

(54) HEATER CIRCUIT, CONTROLLING METHOD THEREOF, AND SUBSTRATE PROCESSING APPARATUS

(71) Applicant: SEMES CO., LTD., Cheonan-si (KR)

(72) Inventor: Byeong Hyeon KONG, Cheonan-si (KR)

(73) Assignee: SEMES CO., LTD., Cheonan-si (KR)

(21) Appl. No.: 18/931,340

(22) Filed: Oct. 30, 2024

(30) Foreign Application Priority Data
Dec. 13, 2023 (KR) 10-2023-0181062

(51) Int. Cl. H01L 21/683; H01J 37/32; H05B 1/02; H05B 3/28

(52) U.S. Cl. CPC H01L 21/6833; H01J 37/32724; H05B 1/0233; H05B 3/283; H01J 2237/2007; H05B 2203/007

(57) ABSTRACT

Proposed are a heater circuit capable of controlling a plurality of heater elements connected in parallel without a diode, a controlling method of the heater circuit, and a substrate processing apparatus. The heater circuit for heating a substrate in the substrate processing apparatus includes a direct current (DC) power source configured to supply a DC voltage, with negative electrode thereof connected to ground, a front-end switch array including front-end switches connected in parallel to a positive electrode of the DC power source, a heater array including heater elements each of which has a front end connected to the front-end switches, a ground switch array including ground switches connected in parallel between rear ends of the heater elements of the heater array and the ground, and a rear-end switch array including rear-end switches connected in parallel between the positive electrode of the DC power source and the ground switches.

### CROSS REFERENCE TO RELATED APPLICATION

The present application claims priority to Korean Patent Application No. 10-2023-0181062, filed Dec. 13, 2024, the entire contents of which are incorporated herein for all purposes by this reference.

### BACKGROUND OF THE INVENTION

### Field of the Invention

The present disclosure relates to a heater circuit for heating a substrate in a substrate processing apparatus, a method for controlling the heater circuit, and the substrate processing apparatus including the heater circuit.

### Description of the Related Art

Semiconductor (or display) manufacturing is a process of manufacturing semiconductor devices on a substrate (e.g., wafer), and includes, for example, exposure, deposition, etching, ion implantation, cleaning, etc. In the case of processes in which a substrate is processed by applying heat energy, such as etching or deposition, it is necessary to control the temperature for each area of the substrate.

Meanwhile, to control the temperature in each area of the substrate, a heater array consisting of a plurality of heater elements is placed on a chuck that supports the substrate, and the power applied to the heater elements is controlled by supplying current to each heater element. Generally, a diode is connected in series to each heater element, and the direction of the current is controlled to be constant by the diode.

However, if overcurrent or breakdown voltage occurs in the diode, the diode is damaged. When the diode is damaged, an error occurs in the overall operation of the heater element, which requires replacement of parts.

### SUMMARY

Accordingly, the present disclosure has been made keeping in mind the above problems occurring in the related art, and an objective of the present disclosure is to provide a heater circuit capable of controlling a plurality of heater elements connected in parallel without a diode, a controlling method of the heater circuit, and a substrate processing apparatus.

In order to achieve the objectives as described above, according to an aspect of the present disclosure, there is provide a heater circuit for heating a substrate in a substrate processing apparatus, the heater circuit including: a direct current (DC) power source configured to supply a DC voltage, with negative electrode thereof connected to ground; a front-end switch array including front-end switches connected in parallel to a positive electrode of the DC power source; a heater array including heater elements each of which has a front end connected to the front-end switches; a ground switch array including ground switches connected in parallel between rear ends of the heater elements of the heater array and the ground; and a rear-end switch array including rear-end switches connected in parallel between the positive electrode of the DC power source and the ground switches.

In an embodiment of the present disclosure, the heater elements of the heater array may be directly connected to the switches of the ground switch array.

In an embodiment of the present disclosure, one of the front-end switches of the front-end switch array may be set to be closed while remaining switches of the front-end switches may be set to be open.

In an embodiment of the present disclosure, one of the ground switches of the ground switch array may be set to be closed while remaining switches of the ground switches may be set to be open.

In an embodiment of the present disclosure, among the rear-end switches of the rear-end switch array, any rear-end switch connected to any ground switch that is open in the ground switch array may be set to be open, while remaining switches of the rear-end switches may be set to be closed.

In an embodiment of the present disclosure, the heater elements of the heater array may have a same resistance value.

In an embodiment of the present disclosure, the heater array may be composed of M×N heater elements (M, N are integers of 2 or more), and the front-end switch array, the ground switch array, and the rear-end switch array may be each controlled according to time in units of M×N.

According to an aspect of the present disclosure, there is provided a controlling method of a heater circuit for heating a substrate in a substrate processing apparatus. The heater circuit may include: a heater array including M×N heater elements (M, N are integers of 2 or more); a DC power source that supplies a DC voltage to the heater array and whose negative electrode is connected to ground; a switch block that controls an electric current supplied to the heater elements of the heater array; and a switch controller that controls the switches of the switch block. The switch block may include: a front-end switch array including M front-end switches connected in parallel to a positive electrode of the DC power source and front ends of the heater elements; a ground switch array including N ground switches connected in parallel between rear ends of the heater elements of the heater array and the ground; and a rear-end switch array including rear-end switches connected in parallel between the positive electrode of the DC power source and the ground switches.

The controlling method of the heater circuit performed by the switch controller may include: closing a first front-end switch of the front-end switch array and opening remaining front-end switches of the front-end switch array during a first duration; and closing a first ground switch of the ground switch array and opening remaining ground switches of the ground switch array during a first duty cycle within the first duration, and opening a first rear-end switch, of the rear-end switch array, connected to the first ground switch and closing remaining rear-end switches of the rear-end switch array during the first duty cycle.

In an embodiment of the present disclosure, the controlling method of the heater circuit may further include closing a second ground switch while opening remaining ground switches in the ground switch array during a second duty cycle after the first duty cycle within the first duration, and opening a second rear-end switch connected to the second ground switch and opening remaining rear-end switches during the second duty cycle.

In an embodiment of the present disclosure, during each duty cycle within the first duration, a process in which one ground switch in the ground switch array is closed and remaining N−1 ground switches are opened, and any rear-end switch, of the rear-end switch array, connected to the closed ground switch is opened and remaining N−1 rear-end switches are opened may be sequentially repeated N times.

In an embodiment of the present disclosure, the controlling method of the heater circuit may further include closing a second front-end switch and opening remaining front-end switches of the front-end switch array during a second duration after the first duration.

In an embodiment of the present disclosure, during each duty cycle within the second duration, a process in which one ground switch in the ground switch array is closed and remaining N−1 ground switches are opened, and any rear-end switch, of the rear-end switch array, connected to the closed ground switch is opened and remaining N−1 rear-end switches are opened may be sequentially repeated N times.

In an embodiment of the present disclosure, a process in which one front-end switch in the front-end switch array is closed and remaining M−1 front-end switches are opened may be sequentially repeated M times.

According to an aspect of the present disclosure, there is provided a substrate processing apparatus including: a chuck configured to support a substrate; a heater array including M×N heater elements (M, N are integers of 2 or more) provided in each heating zone of the chuck; a direct current (DC) power source configured to supply a DC voltage to the heater array and whose negative electrode is connected to ground; a switch block configured to control an electric current supplied to the heater elements of the heater array; and a switch controller configured to control switches of the switch block. The switch block may include: a front-end switch array including M front-end switches connected in parallel to a positive electrode of the DC power source and front ends of the heater elements; a ground switch array including N ground switches connected in parallel between rear ends of the heater elements of the heater array and the ground; and a rear-end switch array including rear-end switches connected in parallel between the positive electrode of the DC power source and the ground switches.

The switch controller may close a first front-end switch of the front-end switch array and open remaining front-end switches of the front-end switch array during a first duration, and may close a first ground switch of the ground switch array and open remaining ground switches of the ground switch array, and may open a first rear-end switch, of the rear-end switch array, connected to the first ground switch and close remaining rear-end switches of the rear-end switch array during a first duty cycle within the first duration. A length of a duty cycle for controlling each switch in the switch block may be determined according to a target supply power of the heater elements.

According to the present disclosure, it is possible to control a plurality of heater elements connected in parallel without a diode.

### BRIEF DESCRIPTION OF THE DRAWINGS

The above and other objectives, features, and other advantages of the present disclosure will be more clearly understood from the following detailed description when taken in conjunction with the accompanying drawings, in which:

FIG. 1 shows the structure of a substrate processing apparatus to which the present disclosure can be applied;

FIGS. 2 and 3 show a substrate processing apparatus according to the present disclosure;

FIG. 4 shows an example of a heater circuit according to the present disclosure;

FIG. 5 is a view for describing the operation of the heater circuit according to the present disclosure;

FIG. 6 shows an equivalent circuit of the heater circuit of FIG. 5;

FIG. 7 is a view for describing a controlling method of the heater circuit according to the present disclosure; and

FIG. 8 is a flowchart showing the controlling method of the heater circuit according to the present disclosure.

### DETAILED DESCRIPTION OF THE INVENTION

Hereinbelow, embodiments of the present disclosure will be described in detail with reference to the accompanying drawings such that the present disclosure can be easily embodied by one of ordinary skill in the art to which the present disclosure belongs. However, the present disclosure is not limited to the embodiments described herein and may be embodied in many different forms.

In order to clearly describe the present disclosure, parts irrelevant to the description are omitted, and the same reference numerals designate the same or similar components throughout the specification.

In addition, in various exemplary embodiments, components having the same configuration will be described only in representative exemplary embodiments by using the same reference numerals, and in other exemplary embodiments, only configurations different from the representative exemplary embodiments will be described.

Throughout the specification, when a part is said to be connected (or coupled) with another part, this includes not only the case of being directly connected (or coupled), but also the case of being indirectly connected (or coupled) with another part in between. In addition, when a certain component is said to be included, this means that other components may also be included without excluding other components unless otherwise stated.

Unless defined otherwise, all terms used herein including technical or scientific terms have the same meanings as generally understood by a person having ordinary knowledge in the art to which the present disclosure pertains. The terms defined in general dictionaries are construed as having meanings consistent with the contextual meanings of the art, but not interpreted as ideal meanings or excessively formal meanings unless explicitly defined in the present application.

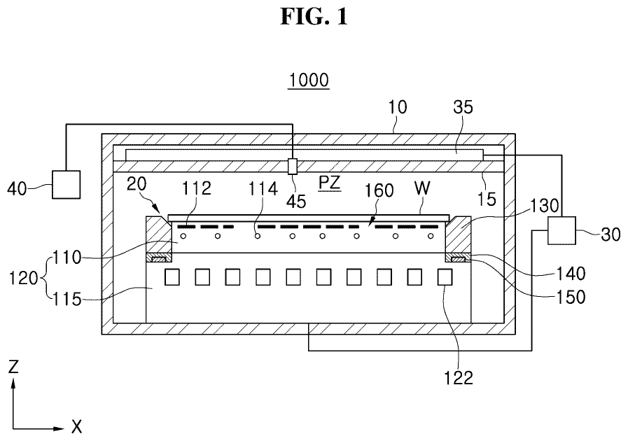

FIG. 1 shows the structure of a substrate processing apparatus 1000 to which the present disclosure can be applied.

The substrate processing apparatus 1000 according to the present disclosure includes: a chamber 10 constituting a plasma processing space PZ for a substrate W; a substrate support assembly 20 supporting the substrate W; an upper electrode 35 generating plasma in the plasma processing space PZ; a window 15 separating the upper electrode 35 from the plasma processing space PZ; an RF power source 30 that supplies power to the upper electrode 35; a gas supply member 45 that supplies processing gas to the plasma processing space PZ; and a gas supply source 40 that provides the processing gas to the gas supply member 45. In addition, although not specifically shown, the substrate processing apparatus 1000 may further include: an opening/closing door that opens or blocks the chamber 10 to external space and a baffle to discharge by-products and gases generated by plasma processing to the outside.

The chamber 10 provides the plasma processing space PZ for the substrate W, and components for plasma processing are installed inside the chamber 10. The window 15, the upper electrode 35, and the gas supply member 45 are located at the upper side of the chamber 10, and the substrate support assembly 20 is located at the lower side of the chamber 10.

The window 15 separates the upper space where the upper electrode 35 is located from the plasma processing space PZ. The window 15 is formed to cover the upper side of the chamber 10 to seal the internal space of the chamber 10. The window may be provided in the shape of a plate (e.g., a disk) and may be made of an insulating material (e.g., alumina (Al2O3)).

The substrate support assembly 20 is provided at the bottom of the chamber 10 and supports the substrate W using electrostatic force. An electrode 112 may be provided inside the substrate support assembly 20 to bring the substrate W into close contact with the substrate support assembly 20 using electrostatic force. The substrate support assembly 20 may function as a lower electrode for generating plasma.

The substrate support assembly 20 includes: an electrostatic chuck 120 supporting the substrate W using electrostatic force, an edge ring 130 surrounding the electrostatic chuck 120; an insulation ring 140 disposed below the edge ring 130; an edge electrode 150 located inside the insulation ring 140.

The electrostatic chuck 120 includes: a ceramic puck 110 on which the substrate W for plasma processing is seated and a heater 114 is built thereinside; and a base plate 115 that supports the bottom of the ceramic puck 110 and has a cooling passage 122 through which fluid for cooling flows. The heater 114 in FIG. 1 may correspond to a heater element of a heater circuit 505 described later.

The ceramic puck 110 is a structure that supports the substrate W from the bottom, and the electrode 112 and the heater 114 are formed therein. The ceramic puck 110 may be made of a ceramic material (e.g., quartz).

The base plate 115 is provided in a disk shape made of metal (e.g., Al). The base plate 115 may be composed of a lower region with a certain diameter and an upper region with a smaller diameter than the lower region. The cooling passage 122 may be formed in the lower region of the base plate 115. The upper region of the base plate 115 may be coupled to the ceramic puck 110. That is, the base plate 115 may have a shape in which the lower region thereof protrudes. Although not shown, the edge ring 130 may be provided on the protruding portion of the base plate 115 to control plasma at the edge of the substrate W.

A coating layer composed of alumina (Al2O3) may be formed on the outer surface of the base plate 115. The coating layer prevents the base plate 115 made of metal (e.g., Al) from being exposed to the external environment, especially plasma. In addition, a bonding layer is formed between the ceramic puck 110 and the base plate 115 to adhere the ceramic puck 110 and the base plate 115.

The RF power source 30 applies power to the upper electrode and the lower electrode provided in the substrate support assembly 20. The RF power source 30 may be provided to control the characteristics of plasma. The RF power source 30 may be provided to regulate ion bombardment energy, for example. In FIG. 1, the RF power source 30 is shown as connected to both the upper electrode 35 and the substrate support assembly 20, but an upper power source connected to the upper electrode 35 and a lower power source connected to the substrate support assembly 20 may be individually configured. Additionally, the upper power source may include a plurality of power sources, and the lower power source may include a plurality of power sources. When a plurality of upper power sources is provided, a matching network electrically connected to the plurality of upper power sources may be provided in the substrate processing apparatus 1000. The matching network may match power of different frequencies input from each of the upper and lower power sources and apply them to the upper electrode 35 and the substrate support assembly 20. Meanwhile, an impedance matching circuit (not shown) may be provided for the purpose of impedance matching on a transmission line connecting the upper power source, the lower power source, the upper electrode 35, and the substrate support assembly 20.

The upper electrode 35 generates plasma from gas remaining in the plasma processing space PZ. In this case, the plasma processing space PZ refers to a space located above the substrate support assembly 20 among the internal spaces of the chamber 10. The upper electrode 35 may generate plasma according to an inductively coupled plasma or a capacitively coupled plasma method. The upper electrode 35 may generate an electromagnetic field from power supplied from the RF power source 30. A matching circuit for impedance matching may be configured between the upper electrode 35 and the RF power source 30.

The gas supply source 40 supplies etching gas used to process the substrate W as a processing gas. The gas supply source 40 may provide a gas containing a fluorine component (e.g., a gas containing SF6 or CF4) as an etching gas to the gas supply member 45.

The gas supply member 45 may be installed at the top side of the chamber 10 to face the substrate support assembly 20 in a vertical direction Z. The gas supply member 45 may be have a plurality of gas injection holes to inject gas into the interior of the chamber 10. The gas supply member 45 may be provided to have a larger diameter than the substrate support assembly 20 in a horizontal direction X. The gas supply member 45 may be a showerhead including a plurality of gas injection holes. In addition, the gas supply member 45 may be a structure having one or more gas supply nozzles. Meanwhile, the gas supply member 45 may be manufactured using silicon ingredients, and may also be manufactured using metal ingredients.

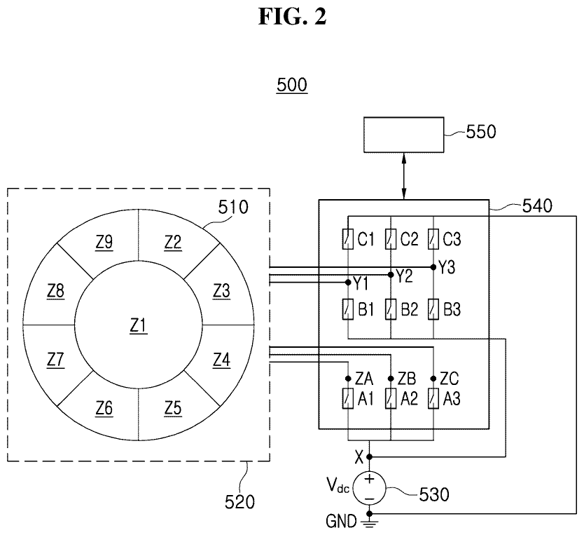

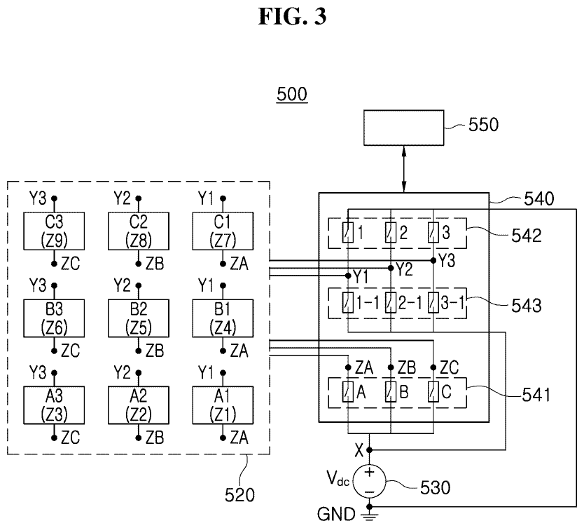

FIGS. 2 and 3 show a substrate processing apparatus 500 to which a heater circuit according to the present disclosure is applied.

The substrate processing apparatus 500 according to the present disclosure includes: a chuck 510 supporting the substrate W; a heater array 520 including M×N heater elements (M, N are integers of 2 or more) provided in each heating zone of the chuck 510; a direct current (DC) power source 530 that supplies DC voltage to the heater array 520 and whose negative electrode is connected to ground; a switch block 540 that controls the current supplied to the heater elements of the heater array 520; and a switch controller 550 that controls switches of the switch block 540. The chuck 510 of FIG. 2 is the electrostatic chuck 120 of FIG. 1, and each heater element belonging to the heater array 520 of FIG. 3 corresponds to the heater 114 of FIG. 1.

The chuck 510 is a structure that supports the substrate W of FIG. 1 from the bottom, and is provided with heater elements therein to heat the substrate W. To control the temperature of each area of the substrate W, a plurality of heating zones is formed in the chuck 510. For example, as shown in FIG. 2, nine heating zones (Z1 to Z9) may be formed. Since output control is required for each heating zone, the power supplied to the heater elements located in the heating zones is individually controlled. The heater circuit 505 according to the present disclosure is provided to control the output of each heater element. As shown in FIG. 3, the heater elements A1, A2, A3, B1, B2, B3, C1, C2, and C3 correspond to the heating zones Z1, Z2, Z3, Z4, Z5, Z6, Z7, Z8, and Z9, respectively.

In this document, the case in which 3×3, or 9, heater elements are arranged is described as an example, but the present disclosure may be applied even when a variety of heater elements, that is, M×N (M is the number of rows and N is the number of columns), are arranged. In this document, the case of M=3 (A, B, C), N=3 (1, 2, 3) is explained as an example.

The DC power source 530 provides a constant DC voltage (Vdc) to the heater array 520. The positive electrode of the DC power source 530 is connected to a node X, and the negative electrode of the DC power source 530 is connected to ground (GND). The switch block 540 is a device that includes a plurality of switches. The switch block 540 may be placed outside or inside the chuck 510. The switches of the switch block 540 may be closed or open by an electrical signal. If the switch of the switch block 540 is in a closed state, both ends of the switch are electrically closed (on state), and if the switch of the switch block 540 is in an open state, both ends of the switch are electrically open (off state). Each switch of the switch block 540 may be implemented with a transistor such as a metal-oxide-semiconductor field-effect transistor (MOSFET).

The switch block 540 includes: a front-end switch array 541 including M front-end switches A, B, and C connected in parallel to the positive electrode of the DC power source 530 and the front ends ZA, ZB, and ZC of the heater elements; a ground switch array 542 including N ground switches 1, 2, and 3 connected in parallel between the rear ends Y1, Y2, and Y3 of the heater elements of the heater array 520 and the ground (GND); and a rear-end switch array 543 including N rear-end switches 1-1, 2-1, and 3-1 connected in parallel between the positive electrode of the DC power source 530 and the ground switches 1, 2, and 3.

Referring to FIG. 3, the front-end switches A, B, and C are connected to the positive electrode of the DC power source 530 through the node X, and are also connected to the front ends ZA, ZB, and ZC of the heater elements, respectively. The front-end switches A, B, and C control the connection between the DC power source 530 and the heater elements. The ground switches 1, 2, and 3 are connected between the rear ends Y1, Y2, and Y3 of the heater elements and the ground (GND). The ground switches 1, 2, and 3 control the connection between the heater elements and the ground (GND). The rear-end switches 1-1, 2-1, and 3-1 are connected to the positive electrode of the DC power source 530 through the node X, and are also connected to the rear ends Y1, Y2, and Y3 of the heater elements, respectively. The rear-end switches 1-1, 2-1, and 3-1 control the connection between the DC power source 530 and the ground switches 1, 2, and 3.

The switch controller 550 controls on (close) and off (open) of each switch of the switch block 540. The switch controller 550 may control the operation of the switches by transmitting control signals to each switch. The switch controller 550 may control the switches according to signals stored internally or input from the outside. The switch controller 550 may be composed of a processor such as a central processing unit (CPU) or an application processor (AP).

The heater circuit 505 may be configured by the DC power source 530, the heater elements included in the heater array 520, and the switches included in the switch block 540 of FIGS. 2 and 3.

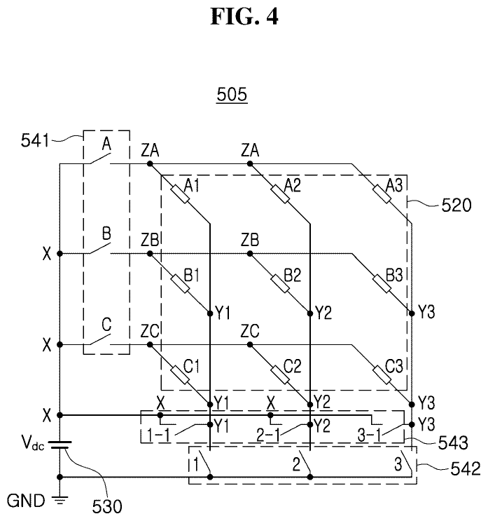

FIG. 4 shows an example of the heater circuit 505 according to the present disclosure. The heater circuit 505 according to the present disclosure includes: the DC power source 530 that supplies DC voltage (Vdc) and whose negative electrode is connected to the ground (GND); the front-end switch array 541 including the front-end switches A, B, and C connected in parallel to the positive electrode of the DC power source 530; the heater array 520 including the heater elements A1, A2, A3, B1, B2, B3, C1, C2, and C3 with front ends ZA, ZB, and ZC connected to the front-end switches A, B, and C, respectively; the ground switch array 542 including the ground switches 1, 2, and 3 connected in parallel between the rear ends Y1, Y2, and Y3 of the heater elements A1, A2, A3, B1, B2, B3, C1, C2, and C3 of the heater array 520 and the ground GND; and the rear-end switch array 543 including the rear-end switches 1-1, 2-1, and 3-1 connected in parallel between the positive electrode of the DC power source 530 and the ground switches 1, 2, and 3.

Referring to FIG. 4, the negative electrode of the DC power source 530 is connected to the ground (GND), and the positive electrode of the DC power source 530 is connected to the node X. The heater array 520 consists of 9 heater elements. The front ends of the heater elements A1, A2, and A3 in the first row are connected to the first front-end switch A through the node ZA, the front ends of the heater elements B1, B2, and B3 in the second row are connected to the second front-end switch B through the node ZB, and the front ends of the third row of heater elements C1, C2, and C3 are connected to the third front-end switch C through the node ZC. The rear ends of the heater elements A1, B1, and C1 in the first row are connected to the first ground switch 1 through the node Y1, the rear ends of the heater elements A2, B2, and C2 in the second row are connected to the second ground switch 2 through the node Y2, and the rear ends of the heater elements A3, B3, and C3 in the third row are connected to the third ground switch 3 through the node Y3. In addition, the first rear-end switch 1-1 in the first row is connected between the node X and the node Y1, the second rear-end switch 2-1 in the second row is connected between the node X and the node Y2, and the third rear-end switch 3-1 in the third row is connected between the node X and the node Y3.

When 3×3 heater elements are arranged, the switches A, B, and C of the front-end switch array 541 control the electrical connection between the DC power source 530 and the heater elements in the corresponding row. The switches 1, 2, and 3 of the ground switch array 542 control the electrical connection between the heater elements in the corresponding row and the ground (GND). The switches 1-1, 2-1, and 3-1 of the rear switch array 543 control the electrical connection between the DC power source 530 and the heater elements in the corresponding row.

In the present disclosure, the heater elements of the heater array 520 are directly connected to the ground switches 1, 2, and 3 of the ground switch array 542. That is, typically, the heater elements are connected to the ground switches 1, 2, and 3 through a diode, but in the present disclosure, the heater elements are directly electrically connected to the ground switches 1, 2, and 3 without a diode. As a replacement of a diode, by controlling the on-off of the rear-end switches 1-1, 2-1, and 3-1 of the rear-end switch array 543, the output of each heater element may be controlled. All heater elements of the heater array 520 may have the same resistance value. Each heater element corresponds to a resistor having the same resistance value R.

According to the present disclosure, one front-end switch (e.g., front-end switch A) of the front-end switch array 541 is set to be closed while the remaining switches (e.g., front-end switches B and C) are set to be open. One ground switch (e.g., ground switch 1) of the ground switch array 542 is set to be closed while the remaining switches (e.g., ground switches 2 and 3) are set to be open. Of the rear-end switch array 543, the rear-end switch (e.g., rear-end switch 1-1) connected to the open ground switch (e.g., ground switch 1) in the ground switch array 542 is set to be open, and the remaining rear-end switches (e.g., rear-end switches 2-1 and 3-1) are set to be closed.

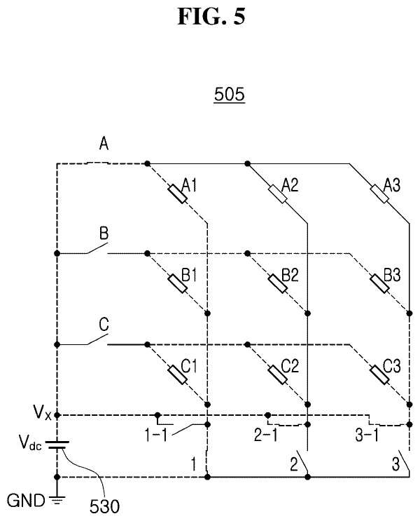

FIG. 5 is a view for describing the operation of the heater circuit 505 according to the present disclosure. For example, as shown in FIG. 5, of the front-end switch array 541, the first front-end switch A may be closed and the remaining second front-end switch B and the third front-end switch C may be open. Of the ground switch array 542, the first ground switch 1 may be closed while the remaining second ground switch 2 and the third ground switch 3 may be open, and the first rear-end switch 1-1 connected to the first ground switch 1 may be open while the remaining second rear-end switch 2-1 and third rear-end switch 3-1 may be closed. In FIG. 5, the dotted line represents the portion where current flows, and the solid line represents the portion where current does not flow.

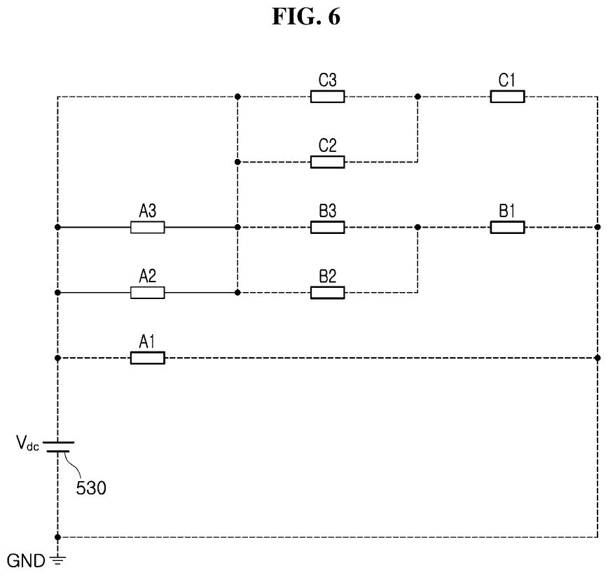

FIG. 6 shows an equivalent circuit of the heater circuit 505 of FIG. 5. As shown in FIG. 6, the DC power source 530 is connected to the front end of the heater element A1 and the ground (GND) is connected to the rear end of the heater element A1, so that DC voltage Vdc is applied to heater element A1. Since both ends of the heater elements A2 and A3 are connected to the positive electrode of the DC power source 530, a voltage of 0 is applied to heater elements A2 and A3. The heater elements B2 and B3 are connected in parallel with each other, and the heater elements B2 and B3 are connected in series with the heater element B1. The voltage applied to the heater element B1 is Vdc*⅔, and the voltage applied to the heater elements B2 and B3 is Vdc*⅓. The heater elements C2 and C3 are connected in parallel with each other, and the heater elements C2 and C3 are connected in series with the heater element C1. The voltage applied to the heater element C1 is Vdc*⅔, and the voltage applied to the heater elements C2 and C3 is Vdc*⅓.

For example, if the DC voltage (Vdc) output by the DC power source 530 is 10 V (Vdc=10V), 10 V is applied to the heater element A1, 6.66 V is applied to the heater elements B1 and C1, 3.33 V is applied to the heater elements B2, B3, C2, and C3, and 0 V is applied to the heater elements A2 and A3.

The power P applied to each heater element is defined as P=V2/R, and if the resistance value (R) of each heater element is 10Ω (R=10≠), the power applied to the heater element A1 is 10 W, the power applied to the heater elements B1 and C1 is 4.44 W, and 1.11 W is applied to the heater elements B2, B3, C2, and C3, whereas 0 W is applied to the heater elements A2 and A3.

After a certain period of time passes, the next switch control process is executed. For example, the process of opening the ground switch 1, with the front-end switch A closed, while closing the rear-end switch 1-1, and closing the ground switch 2 while opening the rear-end switch 2-1 may be performed. In this case, the power applied to the heater element A2 is 10 W, the power applied to the heater elements B2 and C2 is 4.44 W, the power applied to the heater elements B1, B3, C1, and C3 is 1.11 W, and the power applied to the heater elements A1 and A3 is 0 W.

In this way, the power applied to each heater element varies with time. By controlling the on-off time (duration or duty cycle) of each switch, the power applied to each heater element may be individually controlled.

If a 3×3 heater array is calculated as an n×n heater array, n2 time divisions are required. The power applied to each heater element is controlled according to a period (duty cycle) among n2 time division operations. During the entire time division operation, the total power for the heater element A1 is P_{A1}, the duty cycle is D_{A1}, and when the same method is applied to the remaining heater elements, the power applied to each heater element is calculated as Equation 1 below.

$$[ \begin{matrix}{P}_{A 1} \\ {P}_{A 2} \\ {P}_{A 3} \\ {P}_{B 1} \\ {P}_{B 2} \\ {P}_{B 3} \\ {P}_{C 1} \\ {P}_{C 2} \\ {P}_{C 3}\end{matrix} ] = \frac{1}{{n}^{2}} [ \begin{matrix}{P}_{1} & {P}_{4} & {P}_{4} & {P}_{2} & {P}_{3} & {P}_{3} & {P}_{2} & {P}_{3} & {P}_{3} \\ {P}_{4} & {P}_{1} & {P}_{4} & {P}_{3} & {P}_{2} & {P}_{3} & {P}_{3} & {P}_{2} & {P}_{3} \\ {P}_{4} & {P}_{4} & {P}_{1} & {P}_{3} & {P}_{3} & {P}_{2} & {P}_{3} & {P}_{3} & {P}_{2} \\ {P}_{2} & {P}_{3} & {P}_{3} & {P}_{1} & {P}_{4} & {P}_{4} & {P}_{2} & {P}_{3} & {P}_{3} \\ {P}_{3} & {P}_{2} & {P}_{3} & {P}_{4} & {P}_{1} & {P}_{4} & {P}_{3} & {P}_{2} & {P}_{3} \\ {P}_{3} & {P}_{3} & {P}_{2} & {P}_{4} & {P}_{4} & {P}_{1} & {P}_{3} & {P}_{3} & {P}_{2} \\ {P}_{2} & {P}_{3} & {P}_{3} & {P}_{2} & {P}_{3} & {P}_{3} & {P}_{1} & {P}_{4} & {P}_{4} \\ {P}_{3} & {P}_{2} & {P}_{3} & {P}_{3} & {P}_{2} & {P}_{3} & {P}_{4} & {P}_{1} & {P}_{4} \\ {P}_{3} & {P}_{3} & {P}_{2} & {P}_{3} & {P}_{3} & {P}_{2} & {P}_{4} & {P}_{4} & {P}_{1}\end{matrix} ] [ \begin{matrix}{D}_{A 1} \\ {D}_{A 2} \\ {D}_{A 3} \\ {D}_{B 1} \\ {D}_{B 2} \\ {D}_{B 3} \\ {D}_{C 1} \\ {D}_{C 2} \\ {D}_{C 3}\end{matrix} ] \qquad [ Equation 1 ]$$

When V1 is the maximum output voltage of the DC power source 530, P1, P2, P3, and P4 are as in Equation 2 below.

$${V}_{1} = Maximum voltage {V}_{2} = \frac{n - 1}{n} {V}_{1} {V}_{3} = \frac{1}{n} {V}_{1} {V}_{4} = 0 V {P}_{1} = \frac{{V}_{1}^{2}}{R} , {P}_{2} = \frac{{V}_{2}^{2}}{R} , {P}_{3} = \frac{{V}_{3}^{2}}{R} , {P}_{4} = \frac{{V}_{4}^{2}}{R} \qquad [ Equation 2 ]$$

When the target output value (P_{A1}, P_{A2}, . . . , P_{C3}) for each heater element is input, the duty cycle (D_{A1}, D_{A2}, . . . , D_{C3}) for each heater element is calculated through the matrix of Equation 1. By controlling each switch according to the calculated duty cycle, the output of the heater element may be individually controlled. That is, depending on the target supply power (P_{A1}, P_{A2}, . . . , P_{C3}) of the heater elements (A1, A2, . . . , C3), the length of the duty cycle (D_{A1}, D_{A2}, . . . , D_{C3}) for controlling each switch in the switch block 540 may be determined.

When the above method is further generalized and the formula for calculating the duty cycle of the heater array 520 composed of M×N heater elements (M is the number of rows, N is the number of columns) is applied, M×N time divisions are required. That is, in the example of FIGS. 2 to 6, if three rows (A, B, and C) are generalized into M rows and three columns (1, 2, and 3) are generalized into N columns, the power may be calculated as follows.

$$[ \begin{matrix}{P}_{11} \\ … \\ {P}_{1 N} \\ {P}_{21} \\ … \\ {P}_{2 N} \\ … \\ … \\ {P}_{MN}\end{matrix} ] = \frac{1}{M * N} [ \begin{matrix}{P}_{1} & … & {P}_{4} & {P}_{2} & … & {P}_{3} & … & … & {P}_{3} \\ … & ⋱ & & & & & & & \\ {P}_{4} & & ⋱ & & & & & & \\ {P}_{2} & & & ⋱ & & & & & \\ … & & & & ⋱ & & & & \\ {P}_{3} & & & & & ⋱ & & & \\ … & & & & & & ⋱ & & \\ … & & & & & & & ⋱ & \\ {P}_{3} & & & & & & & & ⋱\end{matrix} ] [ \begin{matrix}{D}_{11} \\ … \\ {D}_{1 N} \\ {D}_{21} \\ … \\ {D}_{2 N} \\ … \\ … \\ {D}_{MN}\end{matrix} ] \qquad [ Equation 3 ]$$

When V1 is the maximum output voltage of the DC power source 530, P1, P2, P3, and P4 are as in Equation 4 below.

$${V}_{1} = Maximum voltage {V}_{2} = \frac{N - 1}{N} {V}_{1} {V}_{3} = \frac{1}{N} {V}_{1} {V}_{4} = 0 V {P}_{1} = \frac{{V}_{1}^{2}}{R} , {P}_{2} = \frac{{V}_{2}^{2}}{R} , {P}_{3} = \frac{{V}_{3}^{2}}{R} , {P}_{4} = \frac{{V}_{4}^{2}}{R} \qquad [ Equation 4 ]$$

When the target output value (P_{A1}, P_{A2}, . . . , P_{C3}) for each heater element is input, the duty cycle (D_{A1}, D_{A2}, . . . , D_{C3}) for each heater element is calculated using the matrix of Equation 3. The output of the heater element can be individually controlled by controlling each switch according to the calculated duty cycle.

Hereinafter, a controlling method of the heater circuit 505 according to the present disclosure will be described. The controlling method of the heater circuit 505 may be performed by the switch controller 550 of FIGS. 2 and 3. The switch controller 550 sequentially controls the on-off of each switch and may control the output of each heater element by variably adjusting the length of the duty cycle. In the example below, N duty cycles constitute one duration, and one operating cycle is defined by a total of M durations (i.e., M×N duty cycles).

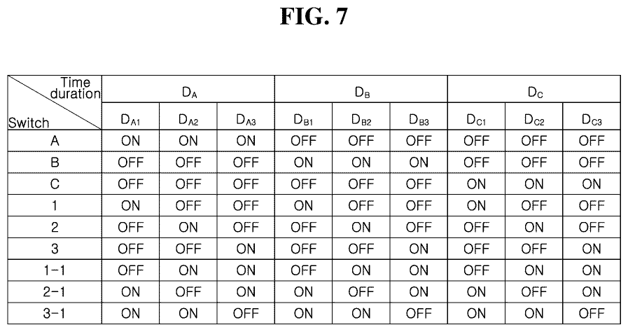

FIG. 7 is a view for describing the controlling method of the heater circuit according to the present disclosure. FIG. 7 shows the switch on-off control method in the case of M=3 and N=3. Duration is defined depending on whether the front-end switches A, B, and C are on or off. Within each duration, the duty cycle is defined according to the on-off of the ground switches 1, 2, and 3 and the rear-end switches 1-1, 2-1, and 3-1. In FIG. 7, “ON” indicates that the switch is closed, and “OFF” indicates that the switch is open.

Referring to FIG. 7, in each duration, among the front-end switches A, B, and C of the front-end switch array 541, only one front-end switch is closed and the remaining front-end switches are open. At each duty cycle within the duration, only one ground switch among the switches 1, 2, and 3 of the ground switch array 542 is closed and the remaining ground switches are open, and conversely, among the rear-end switches 1-1, 2-1, and 3-1 of the rear-end switch array 543, one rear-end switch is open and the remaining rear-end switches are closed. For each duty cycle, the ground switches 1, 2, and 3 and the rear-end switches 1-1, 2-1, and 3-1 are sequentially switched on and off. When n duty cycles are completed, the next duration begins, the front-end switches A, B, and C are switched on and off, and the duty cycle within that corresponding duration is repeated N times. When the duration is repeated M times, the control cycle of the heater circuit 505 ends and the next cycle may begin. The output of each heater element may be changed in each cycle, and the duty cycle may be adjusted according to the changed output of each heater element.

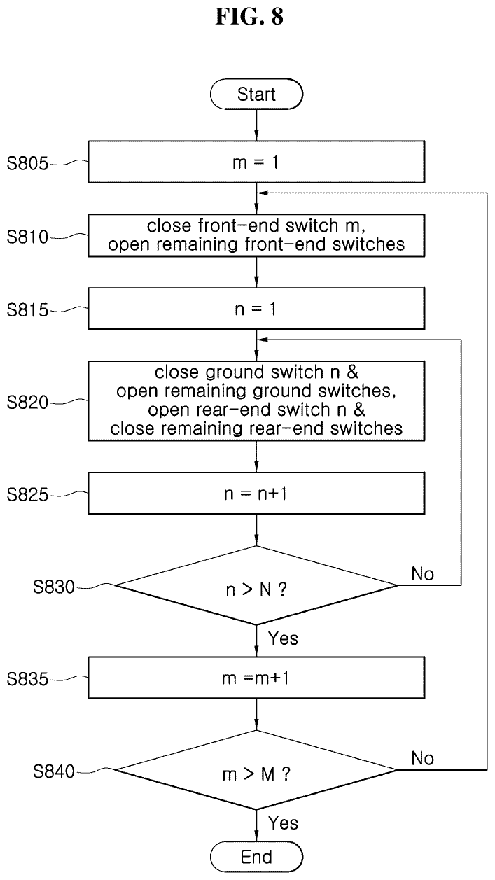

FIG. 8 is a flowchart showing the controlling method of the heater circuit 505 according to the present disclosure. The controlling method of the heater circuit 505 includes: closing the first front-end switch A and opening the remaining front-end switches B and C of the front-end switch array 541 during the first duration DA (S810); and closing the first ground switch 1 and opening the remaining ground switches 2 and 3 of the ground switch array 542 during the first duty cycle D_{A1} within the first duration DA, and opening the first rear-end switch 1-1 connected to the first ground switch 1 and closing the remaining rear-end switches 2-1 and 3-1 of the rear-end switch array 543 during the first duty cycle D_{A1} (S820).

In FIG. 8, m represents the index (or number of durations) of each row in the heater array 520, and n represents the index (or number of duty cycles within the duration) of each column in the heater array 520. In FIG. 8, after the step (S805) of initializing the row index m to 1, the step (S810) of closing the front-end switch (e.g., front-end switch A) of the mth row while opening the remaining front-end switches (e.g., front-end switches B and C) is executed. Thereafter, after the step (S815) of initializing the column index n to 1, the step (S820) of closing the ground switch (e.g., ground switch 1) of the nth column while opening the remaining ground switches (e.g., ground switches 2 and 3), and opening the rear-end switch of the nth column (e.g., rear-end switch 1-1) while closing the remaining rear-end switches (e.g., rear-end switches 2-1 and 3-1) is executed. In step S825, the column index n is increased by 1. In step S830, it is determined whether the duty cycle within the mth duration has ended, that is, whether n is greater than N. When the duty cycle remains in the mth duration (n is less than or equal to N), the ground switch array 542 and the rear-end switch array 543 are switched on and off during the corresponding duty cycle.

For example, the controlling method of the heater circuit 505 may further include: closing the second ground switch 2 in the ground switch array 542 while opening the remaining ground switches 1 and 3 during the second duty cycle D_{A2} after the first duty cycle D_{A1} within the first duration DA, and opening the second rear-end switch 2-1 connected to the second ground switch 2 and opening the remaining rear-end switches 1-1 and 3-1 during the second duty cycle D_{A2}.

That is, during each duty cycle D_{A1}, D_{A2}, or D_{A3} within the first duration DA, a process in which one ground switch (e.g., ground switch 1) among the ground switch array 542 is closed and the remaining N−1 (e.g., two) ground switches (e.g., ground switches 2 and 3) are opened, and the rear-end switch (e.g., rear-end switch 1-1) of the rear-end switch array 543 connected to the closed ground switch (e.g., ground switch 1) is opened and the remaining N−1 (e.g., two) rear-end switches (e.g., 2-1 and 3-1) are opened may be sequentially repeated N times (e.g., 3 times).

The length of each duty cycle is calculated from the output of each heater element as described previously.

When the duty cycle ends at the mth duration (if n is greater than N), in step S835, the row index m is increased by 1, and in step S840, it is determined whether the duration within an operation cycle has ended, that is, whether m is greater than M. When the duration remains in the operation cycle (m is less than or equal to N), during that corresponding duration, by switching the front-end switch array 541 on-off, the front-end switch B in the mth row is closed, and the remaining front-end switches A and C are opened.

For example, the controlling method of the heater circuit 505 may further include: closing the second front-end switch B and opening the remaining front-end switches A and C of the front-end switch array 541 during the second duration DB after the first duration DA.

Thereafter, the ground switch array 542 and the rear-end switch array 543 are switched on and off during the duty cycle within each duration through steps S815 to S830. For example, during each duty cycle D_{A1}, D_{A2}, or D_{A3} within the second duration DB, a process in which one ground switch (e.g., ground switch 1) among the ground switch array 542 is closed and the remaining N−1 (e.g., two) ground switches (e.g., ground switches 2 and 3) are opened, and the rear-end switch (e.g., rear-end switch 1-1) of the rear-end switch array 543 connected to the closed ground switch (e.g., ground switch 1) is opened and the remaining N−1 (e.g., two) rear-end switches (e.g., 2-1 and 3-1) are opened may be sequentially repeated N times (e.g., 3 times).

When the duty cycle ends at the mth duration (if n is greater than N), a process in which the row index m is increased by 1 in step S835, and in step S840, whether the duration within an operation cycle has ended is determined, that is, whether m is greater than M is performed again. When the duration remains in the operation cycle (m is less than or equal to N), during that corresponding duration, a process in which, by switching the front-end switch array 541 on-off, the front-end switch C in the mth (e.g., 3rd) row is closed, and the remaining front-end switches B and C are opened is performed again. That is, a process in which one front-end switch (e.g., front-end switch C) in the front-end switch array 541 is closed and the remaining M−1 (e.g., two) front-end switches (e.g., front-end switch B and C) are opened may be sequentially repeated M times (e.g., 3 times). When the duration within an operation cycle ends (m is greater than M), that operation cycle is completed and the next operation cycle may begin.

Previously, an operation unit of each row composed of N duty cycles was defined as one duration, and it was explained that an operation cycle of the heater circuit 505 is defined by a total of M durations (total M×N duty cycles). On the contrary, the operation unit of each row may be defined as one duty cycle, and the operation unit of each column composed of M duty cycles may be defined as duration, so that the operation cycle of the heater circuit 505 may be defined by a total of N durations (total M×N duty cycles).

The present exemplary embodiment and the accompanying drawings in this specification only clearly show a part of the technical idea included in the present disclosure, and it will be apparent that all modifications and specific exemplary embodiments that can be easily inferred by those skilled in the art within the scope of the technical spirit contained in the specification and drawings of the present disclosure are included in the scope of the present disclosure.

Therefore, the spirit of the present disclosure should not be limited to the described exemplary embodiments, and all things equal or equivalent to the claims as well as the claims to be described later fall within the scope of the concept of the present disclosure.

What is claimed is:

1. A heater circuit for heating a substrate in a substrate processing apparatus, the heater circuit comprising:
a direct current (DC) power source configured to supply a DC voltage, with negative electrode thereof connected to ground;
a front-end switch array including front-end switches connected in parallel to a positive electrode of the DC power source;
a heater array including heater elements each of which has a front end connected to the front-end switches;
a ground switch array including ground switches connected in parallel between rear ends of the heater elements of the heater array and the ground; and
a rear-end switch array including rear-end switches connected in parallel between the positive electrode of the DC power source and the ground switches.

2. The heater circuit of claim 1, wherein the heater elements of the heater array are directly connected to the switches of the ground switch array.

3. The heater circuit of claim 1, wherein one of the front-end switches of the front-end switch array is set to be closed while remaining switches of the front-end switches are set to be open.

4. The heater circuit of claim 3, wherein one of the ground switches of the ground switch array is set to be closed while remaining switches of the ground switches are set to be open.

5. The heater circuit of claim 4, wherein among the rear-end switches of the rear-end switch array, any rear-end switch connected to any ground switch that is open in the ground switch array is set to be open, while remaining switches of the rear-end switches are set to be closed.

6. The heater circuit of claim 1, wherein the heater elements of the heater array have a same resistance value.

7. The heater circuit of claim 1, wherein the heater array is composed of M×N heater elements (M, N are integers of 2 or more), and
the front-end switch array, the ground switch array, and the rear-end switch array are each controlled according to time in units of M×N.

8. A controlling method of a heater circuit for heating a substrate in a substrate processing apparatus, wherein the heater circuit comprises: a heater array including M×N heater elements (M, N are integers of 2 or more); a DC power source that supplies a DC voltage to the heater array and whose negative electrode is connected to ground; a switch block that controls an electric current supplied to the heater elements of the heater array; and a switch controller that controls the switches of the switch block, wherein the switch block comprises: a front-end switch array including M front-end switches connected in parallel to a positive electrode of the DC power source and front ends of the heater elements; a ground switch array including N ground switches connected in parallel between rear ends of the heater elements of the heater array and the ground; and a rear-end switch array including rear-end switches connected in parallel between the positive electrode of the DC power source and the ground switches, the method performed by the switch controller comprising:
closing a first front-end switch of the front-end switch array and opening remaining front-end switches of the front-end switch array during a first duration; and
closing a first ground switch of the ground switch array and opening remaining ground switches of the ground switch array during a first duty cycle within the first duration, and opening a first rear-end switch, of the rear-end switch array, connected to the first ground switch and closing remaining rear-end switches of the rear-end switch array during the first duty cycle.

9. The method of claim 8, further comprising:
closing a second ground switch while opening remaining ground switches in the ground switch array during a second duty cycle after the first duty cycle within the first duration, and opening a second rear-end switch connected to the second ground switch and opening remaining rear-end switches during the second duty cycle.

10. The method of claim 8, wherein during each duty cycle within the first duration, a process in which one ground switch in the ground switch array is closed and remaining N−1 ground switches are opened, and any rear-end switch, of the rear-end switch array, connected to the closed ground switch is opened and remaining N−1 rear-end switches are opened is sequentially repeated N times.

11. The method of claim 8, further comprising:
closing a second front-end switch and opening remaining front-end switches of the front-end switch array during a second duration after the first duration.

12. The method of claim 11, wherein during each duty cycle within the second duration, a process in which one ground switch in the ground switch array is closed and remaining N−1 ground switches are opened, and any rear-end switch, of the rear-end switch array, connected to the closed ground switch is opened and remaining N−1 rear-end switches are opened is sequentially repeated N times.

13. The method of claim 12, wherein a process in which one front-end switch in the front-end switch array is closed and remaining M−1 front-end switches are opened is sequentially repeated M times.

14. The method of claim 8, wherein the heater elements of the heater array are directly connected to the switches of the ground switch array.

15. The method of claim 8, wherein the heater elements of the heater array have a same resistance value.

16. A substrate processing apparatus, comprising:
a chuck configured to support a substrate;
a heater array including M×N heater elements (M, N are integers of 2 or more) provided in each heating zone of the chuck;
a direct current (DC) power source configured to supply a DC voltage to the heater array and whose negative electrode is connected to ground;
a switch block configured to control an electric current supplied to the heater elements of the heater array; and
a switch controller configured to control switches of the switch block,
wherein the switch block comprises:
a front-end switch array including M front-end switches connected in parallel to a positive electrode of the DC power source and front ends of the heater elements;
a ground switch array including N ground switches connected in parallel between rear ends of the heater elements of the heater array and the ground; and
a rear-end switch array including rear-end switches connected in parallel between the positive electrode of the DC power source and the ground switches,
the switch controller
closes a first front-end switch of the front-end switch array and opens remaining front-end switches of the front-end switch array during a first duration, and
closes a first ground switch of the ground switch array and opens remaining ground switches of the ground switch array, and opens a first rear-end switch, of the rear-end switch array, connected to the first ground switch and closes remaining rear-end switches of the rear-end switch array during a first duty cycle within the first duration, and
a length of a duty cycle for controlling each switch in the switch block is determined according to a target supply power of the heater elements.

17. The apparatus of claim 16, wherein during each duty cycle within the first duration, a process in which one ground switch in the ground switch array is closed and remaining N−1 ground switches are opened, and any rear-end switch, of the rear-end switch array, connected to the closed ground switch is opened and remaining N−1 rear-end switches are opened is sequentially repeated N times.

18. The apparatus of claim 16, wherein a process in which one front-end switch in the front-end switch array is closed and remaining M−1 front-end switches are opened is sequentially repeated M times.

19. The apparatus of claim 16, wherein the heater elements of the heater array are directly connected to the switches of the ground switch array.

20. The apparatus of claim 16, wherein the heater elements of the heater array have a same resistance value.
